(19) United States
(12) Patent Application Publication
(10) Pub. No.: US 2015/0298232 A1
(43) Pub. Date: Oct. 22, 2015

(54) METHOD FOR PRE-SOLDERING METAL SURFACES ONTO METALIZED SUBSTRATES USING A METALLIC GAUZE, METALIZED SUBSTRATES WITH A SOLDER LAYER WHICH HAS A SUPERFICIAL STRUCTURE OF A GAUZE

(71) Applicant: CERAMTEC GMBH, Plochingen (DE)

(72) Inventor: Klaus Herrmann, Thiersheim (DE)

(21) Appl. No.: 14/650,020

(22) PCT Filed: Dec. 13, 2013
(86) PCT No.: PCT/EP2013/076466

§ 371 Date: Jun. 5, 2015

(30) Foreign Application Priority Data
Dec. 18, 2012 (DE) 10 2012 223 601.5

(51) Int. Cl. B23K 1/008; B23K 35/02; B23K 35/26; H05K 3/34

(52) U.S. Cl. CPC B23K 1/008; H05K 3/3478; H05K 3/3494; B23K 35/0222; B23K 35/262; H05K 2203/0415

(57) ABSTRACT

A method for pre-soldering metal surfaces onto metallized substrates (1a, 1b), wherein solder preforms (2a, 2b) are placed onto the metal surfaces of the substrates (1a, 1b) or vice versa, after which the solder preforms (2a, 2b) are fused. To achieve a defined, consistent height of the solder layer, inhibit the formation of bulged solder, enable the production of even thicker solder layers of around 100 μm with a thickness fluctuation of below 20 μm to the edge of the solder layer and minimize a pore formation in the solder layer, a metallic gauze (3a, 3b) is pressed flat onto the solder preforms (2a, 2b) during the soldering or fusing processes, the metallic gauze (3a, 3b) consisting of a solder-wetting material.

The invention relates to a method for pre-soldering metal surfaces onto metallized substrates, wherein solder preforms are placed onto the metal surfaces of the substrates or vice versa, after which the solder preforms are melted, whereby the metal surfaces are soldered with the solder of the solder preforms and the solder forms a solder layer.

Electrical components are often set on metal surfaces of metalized substrates such as metallized ceramics or metal-clad plastics or plastic boards (such as FR4). Of particular interest are substrates with metal surfaces that are already pre-soldered and therefore can be immediately fitted with components in a continuous furnace.

Particularly desired is pre-soldering that does not have the usual meniscus, so that the components put in place for soldering do not wobble or migrate. In the usual pre-soldering metal surfaces with solder, usually on the basis of nickel or silver or silver/palladium, with screen-printed solder balls or with solder film blanks, the liquid solder forms a clear edge angle.

Until now, the solder preforms have been flattened in complicated dies during melting, which nonetheless led to unsatisfactory surfaces.

It is the object of the invention to improve a method according to the preamble of claim 1 such that a defined, uniform height of the solder layer is achieved and a solder bulge is not formed. Furthermore, even thicker solder layers around 100 μm with a thickness variation of less than 20 μm to the edge of the solder layer are to be produced. Pore formation in the solder layer is also to be minimized.

According to the invention, this object is achieved by the features of claim 1.

By virtue of the fact that a metallic gauze is pressed on the solder preforms during soldering or fusing and the metallic gauze is made of a non-solder wetting material, a defined, uniform height of the solder is achieved, and there is no formation of a solder bulge. In addition, even thicker solder layers of around 100 μm with a thickness variation of less than 20 or even less than 15 μm to the edge of the solder layer are obtained. Pore formation is also to be minimized in the solder layer. In this way , the electrical or electronic component, such as a chip/transistor etc., can be laid on a uniformly thick solder layer in a later process. The heat conduction from the component into the substrate is more uniform and calculable.

In this description, the term “solder preforms” also includes only one solder preform. Metallic gauzes are also designated as metallic screen cloth and used in screen printing, for example.

The metallic gauzes should be pressed as flat as possible on the solder preforms (preferably tensioned), so that the solder layer is uniformly high.

The invention is based on the idea that the melting solder can be pressed flat using a flat preferably tensioned metallic gauze (as is used for example in screen printing) made of a suitable, non-solder wetting material.

The gas in the soldering furnace is able to escape through the openings in the metallic gauze and does not form bubbles in the solder or in the surface of the solder layer.

The metallic gauze is made of a non-solder wetting material, so that it does not bond with the usual soft solders based on tin. In addition, the metallic gauze does not scale in a neutral or reducing atmosphere. The metallic gauze is preferably a stainless steel gauze.

The thickness or height of the metallic gauze can be used to define the thickness or height of the solder layer on the metal surfaces.

Preferably, flat leaf-shaped solder blanks are used as the solder preforms, which can be easily placed on the metal surfaces, and which exist in every desired thickness. The useable solders are preferably modern lead-free soft solders such as, for example, the solder group SnCuₓAg_{y}. Preferably the solder is made of SnAg₃Cu_{0.5}.

Preferably the height (thickness) of the solder preforms and the volume between the metal threads of the metallic gauze are adapted to one another in such a way that the melting solder maximally fills this volume but does not “run over” and is not pressed to the side over the edge of the metal surfaces. If excessively high solder preforms are used, “runover” occurs. If solder preforms are used that are too low or too thin, the solder does not completely fill the space between the metal threads of the metallic gauze, so that the height of the later solder layer is not defined.

In one preferred embodiment of the method for soldering, in a substrate with metal surfaces on both sides a sandwich is formed from the following parts arranged one over the other:

a. a flat base plate, preferably of ceramic

b. metallic gauze

c. solder preforms

d. substrate with metal surfaces on two sides

e. solder preforms

f. metallic gauze

g. flat cover plate, preferably of ceramic.

This sandwich, possibly still under pressure, is heated in a furnace until the solder preforms melt and the melted solder solders the metal surfaces. After that, the sandwich is taken from the furnace and cooled. Finally the metallic gauze can be taken from the substrate and reused.

For a substrate with metal surfaces on only one side, letters e and f are not applicable, that is, the cover plate is laid directly on the side of the substrate without metal surfaces.

Preferably, the mesh width of the metallic gauze is between 300 and 450 mesh, preferably at 325 or 400 mesh. The best results were obtained with these mesh widths. Preferably, stainless steel gauze such as VA325 or VA280 is used (the number describes the thread count per inch).

For a metallized substrate according to the invention with soldered metal surfaces, in particular produced by the just described method, the solder layer on the metal surfaces has a surface structure similar to a gauze. The solder layer has a uniform height and no bulges. The thickness variation of the solder layer on the metal surfaces is less than 20 μm.

The invention thus also describes a method by which the pre-soldering can be carried out in order to obtain flat solder deposits in a defined, uniform thickness on a substrate. The method can be used both for unilateral and bilateral soldering of substrates.

Further features of the invention can be derived from the figures described below.

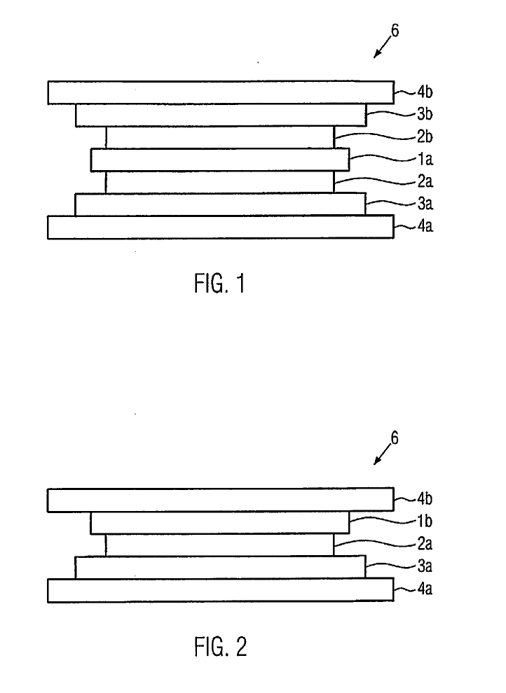

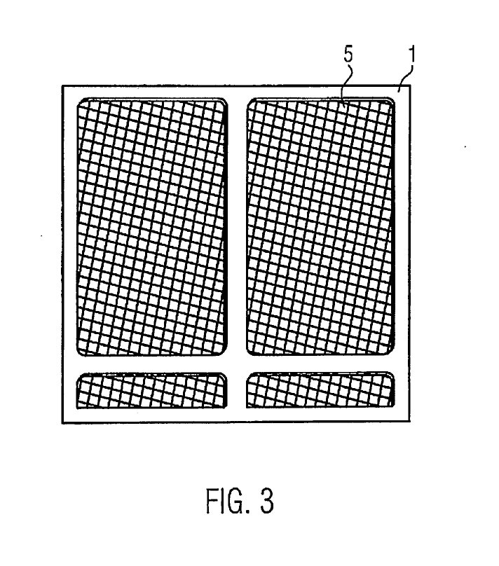

FIG. 1 shows a fusion mold or a sandwich 6 with which soldering or a solder layer 5 (see FIG. 3) can be placed on metal surfaces of a metallized substrate 1. The fusion mold or sandwich 6 consists of the following parts, which are layered one atop the other.

The individual layers or parts of the sandwich 6 are not shown true to scale in FIGS. 1 and 2. These are merely to demonstrate the layering or the structure of the fusion mold.

A flat base plate 4a made of graphite, aluminum, or ceramic is located at the very bottom. Ceramic is preferred. On top of that is a metallic gauze 3a made of a non-solder wetting material. Here, it is a steel gauze, that is, a metallic gauze 3a, made of individual steel threads. The mesh width of this metallic gauze 3a is 325 mesh or 400 mesh. The metallic gauze 3a is preferably tensioned. For example, it can be secured in a tensioned manner on the base plate 4a. However, it can also be simply placed on the base plate 4a, as the sandwich 6 is weighted down during soldering by the plates 4a, 4b or is additionally tensioned.

A solder preform 2a or several solder preforms are arranged on the metallic gauze 3a. The individual solder preforms 2 must be arranged on the sites of the metal surfaces to be soldered on the substrate 1.

In the figures, reference symbols 1a and 1b are used to designate the metallized substrates with their metal surfaces. The fusion mold or the sandwich in FIG. 1 has a substrate 1a with metal surfaces on both sides.

For soldering of the other side of the substrate 1a, a solder preform 2b or several solder preforms are arranged on the latter. An additional metallic gauze 3b is placed on this solder preform 2b. A flat cover plate 4b is arranged at the very top of the sandwich 6.

FIG. 2 shows a fusion mold or sandwich for soldering of only one side of the substrate.

A flat base plate 4a made of ceramic is located at the very lowest part. A metallic gauze 3a lies upon it which is made of non-solder wetting material, here a steel gauze. The mesh width of this metallic gauze 3a is 325 mesh or 400 mesh. The metallic gauze 3a is secured in a tensioned state on the base plate 4a (which cannot be identified in the figure). However, it can be simply laid on the base plate 4a, as the sandwich 6 is weighted down by the plates during soldering, or it is additionally tensioned.

A solder preform 2a or several solder preforms are arranged on the metallic gauze 3a. The individual solder preforms 2 must be arranged on the sites of the metal surfaces to be soldered of the substrates 1.

The substrate to be soldered is designated with the reference symbol 1b. The fusion mold on the sandwich 6 in FIG. 1 has a substrate 1b with metal surfaces on only one side. The sandwich is covered with a cover plate 4b, which here is made of ceramic.

In addition, in all examples the substrate is pre-metallized with W-glass+NiP (possibly also+Au).

For soldering, the sandwich is treated for example in a continuous furnace or in a batch furnace or other heating unit (IR furnaces or the like).

The furnace atmosphere must be adapted to the materials; it preferably consists of nitrogen or a mixture of nitrogen and hydrogen. The peak temperature in the furnace is adapted to the solder and is preferably in a range of 300-600° C. The melting time of the solder must be kept as brief as possible and is less than 5 minutes.

Metallized substrates are metallized ceramics or metallized cladding or plastic boards, for example.

Basically, during soldering, a flat (for example polished) plate 4a, 4b preferably made of ceramic is flatly coated on one side with a metallic gauze made of stainless steel or tensioned. The solder preforms, i.e., the flat leaf-shaped solder blanks, are placed on the flat metallic gauze in defined places. This can be done using a robot. The substrate to be soldered with its base metallization such as W—Ni or Cu—Ni or the like is then placed on the solder preforms.

If the substrate is metallized on both sides, solder preforms can now also be laid on the surfaces of the top side of the solder preforms to be soldered. A metallic gauze is then also placed on the coated top side and a flat ceramic plate as the cover plate 4b.

The “sandwich” can additionally still be weighted down by further weights to improve contact. The sandwich is then passed through a furnace and the solder preforms are melted. The thickness of the solder preform and the “color volume” of the metallic gauze are adapted to one another in such a way that the solder maximally fills the empty space between the metal threads but does not “overflow” and is not pressed to the side over the margin of the metal surfaces to be soldered. The solder surface is plated by the lower base plate 4a and the upper cover plate 4b.

The background of the method relates to the poor wetting of stainless steel (metallic gauze) by many tin-containing solders. Thus, following the pre-soldering, the metallic gauze can simply be extracted from the re-hardened solder and reused.

The imparting of structure to the solder layer by a non-wetting means, here a metallic gauze or a screen gauze with which the solder thickness can also be controlled along with the height or thickness of the solder preform, is an important feature of the invention.

FIG. 3 shows the solder layer on a substrate 1 according to the invention with a solder layer 5. The solder layer 5 is arranged on the metal surfaces (below the solder layer 5, so not visible) and has a surface structure similar to a gauze.

The solder layer 5 has a uniform height and no bulges. The thickness variation of the solder layer 5 on the metal surfaces is less than 20 μm, and preferably less than 15 μm.

1-11. (canceled)

12. A method for pre-soldering metal surfaces on metallized substrates comprising placing solder preforms on the metal surfaces of the substrates and subsequently melting the solder preforms, whereby the metal surfaces are soldered with the solder of the solder preforms and the solder forms a solder layer, and pressing flat a metallic gauze on the solder preforms during soldering or melting, wherein the metallic gauze is made of a non-solder wetting material.

13. The method according to claim 12, wherein leaf-shaped solder blanks are used as the solder preforms.

14. The method according to claim 12, wherein the metallic gauze is a stainless steel gauze.

15. The method according to claim 12, wherein the height of the solder preforms and the volume between the metal threads of the metallic gauze are adapted to one another such that the melting solder maximally fills this volume but does not overflow and is not pushed to the side over the margin of the metal surfaces.

16. The method according to claim 12, wherein, in a substrate with bilateral metal surfaces for soldering, a sandwich is formed from the following parts, which are arranged one above the other:
a. a flat base plate;
b. metallic gauze;
c. solder preforms;
d. substrate with bilateral metal surfaces;
e. solder preforms;
f. metallic gauze; and
g. flat cover plate;
and wherein the sandwich is heated in a furnace until the solder preforms melt and the melting solder solders the metal surfaces, after which the sandwich is removed from the furnace and cooled, and wherein the metallic gauze is removed from the substrate and reused.

17. The method according to claim 12,
wherein, in a substrate with bilateral metal surfaces for soldering, a sandwich is formed from the following parts, which are arranged one above the other:
a) a flat base plate;
b) metallic gauze;
c) solder preforms;
d) substrate with a metal surface; and
e) flat cover plate;
and wherein the sandwich is heated in a furnace until the solder preforms melt and the melting solder solders the metal surfaces, after which the sandwich is removed from the furnace and cooled, and wherein the metallic gauze is removed from the substrate and reused.

18. The method according to claim 12, wherein the mesh width of the metallic gauze is between 300 and 450 mesh.

19. The method according to claim 12, wherein the solder preforms comprise SnAg₃Cu_{0.5}.

20. A metallized substrate with soldered metal surfaces produced with the method according to claim 12, wherein the solder layer on the metal surfaces has a surface structure similar to gauze.

21. The metallized substrate according to claim 20, wherein the solder layer has a uniform height and no bulges.

22. The metallized substrate according to claim 20, wherein the thickness variation of the solder layer on the metal surfaces is less than 20 μm.

23. The method according to claim 13, wherein the metallic gauze is a stainless steel gauze.

24. The method according to claim 13, wherein the height of the solder preforms and the volume between the metal threads of the metallic gauze are adapted to one another such that the melting solder maximally fills this volume but does not overflow and is not pushed to the side over the margin of the metal surfaces.

25. The metallized substrate according to claim 21, wherein the thickness variation of the solder layer on the metal surfaces is less than 20 μm.

26. The method according to claim 22, wherein the metallic gauze is a stainless steel gauze.
